(19) United States
(12) Patent Application Publication
(10) Pub. No.: US 2011/0260248 A1
(43) Pub. Date: Oct. 27, 2011

(54) SOI Wafer and Method of Forming the SOI Wafer with Through the Wafer Contacts and Trench Based Interconnect Structures that Electrically Connect the Through the Wafer Contacts

(76) Inventors: Peter Smeys, San Jose, CA (US); Peter Johnson, Sunnyvale, CA (US); Peter J. Hopper, San Jose, CA (US); William French, San Jose, CA (US)

(21) Appl. No.: 12/768,295

(22) Filed: Apr. 27, 2010

(51) Int. Cl. H01L 29/786; H01L 21/768

(52) U.S. Cl. 257/347; 438/655; 257/E29.273; 257/E21.585

(57) ABSTRACT

A silicon-on-insulator (SOI) wafer is formed to have through-the-wafer contacts, and trench based interconnect structures on the back side of the SOI wafer that electrically connect the through-the-wafer contacts. In addition, selected ones of the through-the-wafer contacts bias the bodies of the MOS transistors.

### BACKGROUND OF THE INVENTION

1. Field of the Invention

The present invention relates to an SOI wafer and, more particularly, to an SOI wafer and a method of forming the SOI wafer with through the wafer contacts and trench based interconnect structures that electrically connect the through the wafer contacts.

2. Description of the Related Art

A silicon-on-insulator (SOI) wafer is a well-known wafer structure that includes a thin silicon layer which is separated from a bulk silicon region by a buried insulation layer. In addition, SOI wafers typically include a shallow trench isolation (STI) region that extends through the thin silicon layer to form a large number of isolated silicon regions.

The isolated silicon regions, in turn, commonly function as the bodies of MOS transistors, which benefit from being electrically isolated from the bulk silicon region as well as from laterally adjacent devices. For example, SOI-based MOS transistors have a lower parasitic capacitance as a result of being electrically isolated, and are thereby faster than conventional MOS transistors.

FIG. 1 shows a cross-sectional view that illustrates an example of a conventional partially-processed SOI wafer 100. As shown in FIG. 1, SOI wafer 100 includes a bulk silicon region 110, a large number of thin silicon regions 112, and a buried insulation layer 114 that lies between and touches bulk silicon region 110 and the thin silicon regions 112. (Only one thin silicon region 112 is shown for clarity.)

As further shown in FIG. 1, SOI wafer 100 includes an STI region 116 that extends down to touch buried insulation layer 114. Thus, each thin silicon region 112 is electrically isolated from bulk silicon region 110 by buried insulation layer 114, and is also electrically isolated from laterally adjacent silicon regions 112 by STI region 116. (A field oxide region, which is formed by the well-known local oxidation of silicon process, can alternately be used in lieu of an STI region.)

SOI wafer 100 additionally includes a MOS transistor 120 that has spaced-apart source and drain regions 122 and 124 that are formed in thin silicon region 112, and a channel region 126 of thin silicon region 112 that lies between and touches the source and drain regions 122 and 124. The source and drain regions 122 and 124, which each have a heavily-doped region HD and a lightly-doped region LD, have a conductivity type that is opposite to the conductivity type of thin silicon region 112, which functions as the body of MOS transistor 120.

MOS transistor 120 also includes a gate oxide layer 130 that touches the top surface of thin silicon region 112 over channel region 126, and a gate 132 that touches the top surface of gate oxide layer 130 over channel region 126. Gate 132 is typically implemented with polysilicon. Further, MOS transistor 120 includes a side wall spacer 134 that touches the side walls of gate 132.

As additionally shown in FIG. 1, SOI wafer 100 includes a dielectric layer 140 that lies over and touches STI region 116, the source and drain regions 122 and 124, gate 132, and side wall spacer 134. As noted above, SOI wafer 100 is a partially completed SOI wafer and, as a result, does not illustrate all of the remaining structures required to make an operational circuit.

As further noted above, one of the advantages of SOI wafer 100 is that SOI wafer 100 reduces the parasitic capacitance of MOS transistor 120. Another advantage of SOI wafer 100 is that STI region 116 defines silicon regions 112 that are very compact, thereby increasing the number of MOS transistors that can be formed in a given area.

However, although the isolation provided by SOI wafer 100 reduces the parasitic capacitance and increases the device density, the isolation provided by SOI wafer 100 also makes it difficult to from an electrical contact to the body (thin silicon region 112) of MOS transistor 120. As a result, MOS transistor 120 commonly operates with an electrically floating body.

An electrically floating body, however, can cause the threshold voltage of the MOS transistor to vary which, in turn, can introduce delays into the operation of the circuit. While a circuit can be designed to account for these effects, transistors with biased bodies do not suffer from these problems and are therefore preferred.

### BRIEF DESCRIPTION OF THE DRAWINGS

FIG. 1 is a cross-sectional view illustrating an example of a conventional partially-processed SOI wafer 100.

FIGS. 2-19 are cross-sectional views illustrating an example of a method of forming an electronic circuit on an SOI wafer in accordance with the present invention.

FIG. 20 is a cross-sectional view illustrating an example of an alternate embodiment of the present invention.

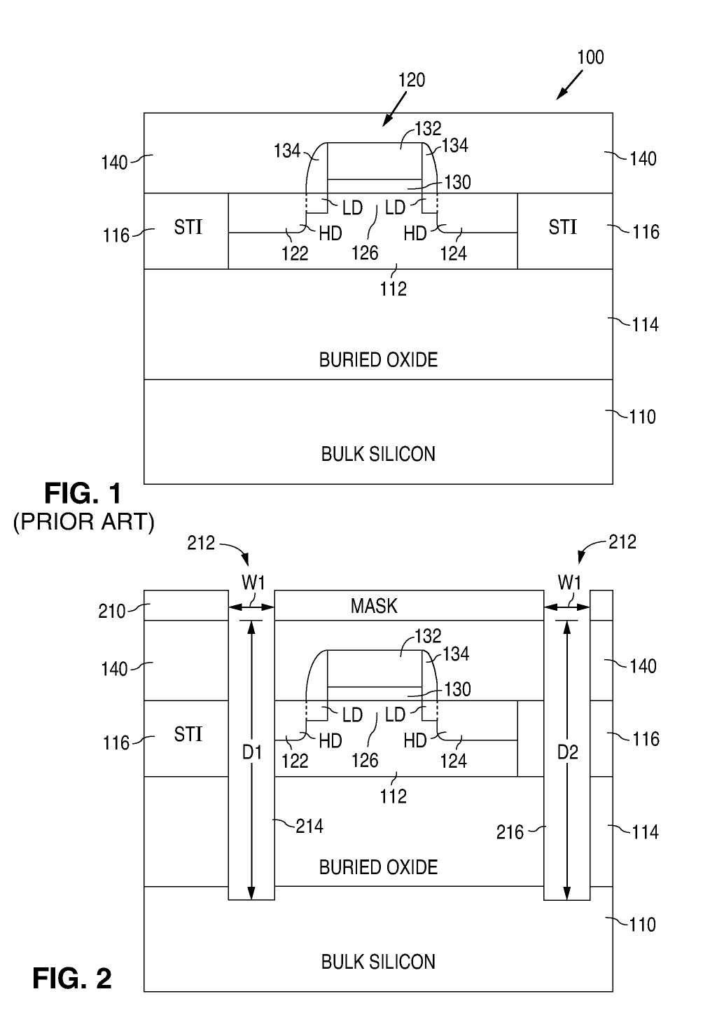

### DETAILED DESCRIPTION OF THE INVENTION

FIGS. 2-19 show cross-sectional views that illustrate an example of a method of forming an electronic circuit on an SOI wafer in accordance with the present invention. As described in greater detail below, the present invention is an SOI wafer and a method of forming the SOI wafer with through-the-wafer contacts, and trench based interconnect structures that electrically connect the through-the-wafer contacts. In addition, selected ones of the through-the-wafer contacts bias the bodies of the MOS transistors.

As shown in FIG. 2, the method of the present invention utilizes SOI wafer 100, and begins by forming a masking material on the top surface of dielectric layer 140. The masking material is then patterned to form a mask 210 that has a number of openings 212 that expose the top surface of dielectric layer 140.

Each of the openings 212, in turn, has a maximum cross-sectional width W1. After mask 210 has been formed, the regions exposed by the openings 212 in mask 210 are etched, such as with a timed plasma etch, until a portion of bulk silicon region 110 has been removed. Following this, mask 210 is removed.

In accordance with the present invention, the etch forms a first opening 214 with a depth D1 that extends through a portion of dielectric layer 140, a portion of source region 122, a portion of thin silicon region 112, a portion of buried insulation layer 114, and into bulk silicon region 110. (Opening 214 can also extend through a portion of the adjacent STI region 116.) The etch also forms a second opening 216 with a depth D2 that extends through a portion of dielectric layer 140, a portion of STI region 116, a portion of buried insulation layer 114, and into bulk silicon region 110. The depths D1 and D2 are approximately equal.

In further accordance with the present invention, the depths D1 and D2 are approximately four times the widths W1 of the openings 212 in mask 210. As a result, the first and second openings 214 and 216 have an aspect ratio of approximately 4:1. The openings 214 and 216 can be formed by reducing the C:F ratio of a typical contact etch. In addition, a C₂F₆ etch chemistry, without CHF₃ which is typically added for selectivity to silicon, would also probably be acceptable.

Bulk silicon region 110 should not be excessively etched. For example, if dielectric layer 140 is approximately 0.7 μm thick, thin silicon region 112 is approximately 0.2 μm thick, buried insulation layer 114 is approximately 3 μm thick, the widths W1 of the openings 212 are approximately 1 μm, and the depths D1 and D2 of the openings 214 and 216 are approximately 4 μm, then approximately 0.1 μm of bulk silicon region 110 is etched away. However, it is acceptable to penetrate further, such as up to 0.5 μm into bulk silicon region 110. In addition, since buried insulation layer 114 is typically much thicker than the thin silicon regions 112, utilizing an SOI wafer with a thinner buried insulation layer allows openings with smaller widths to be formed.

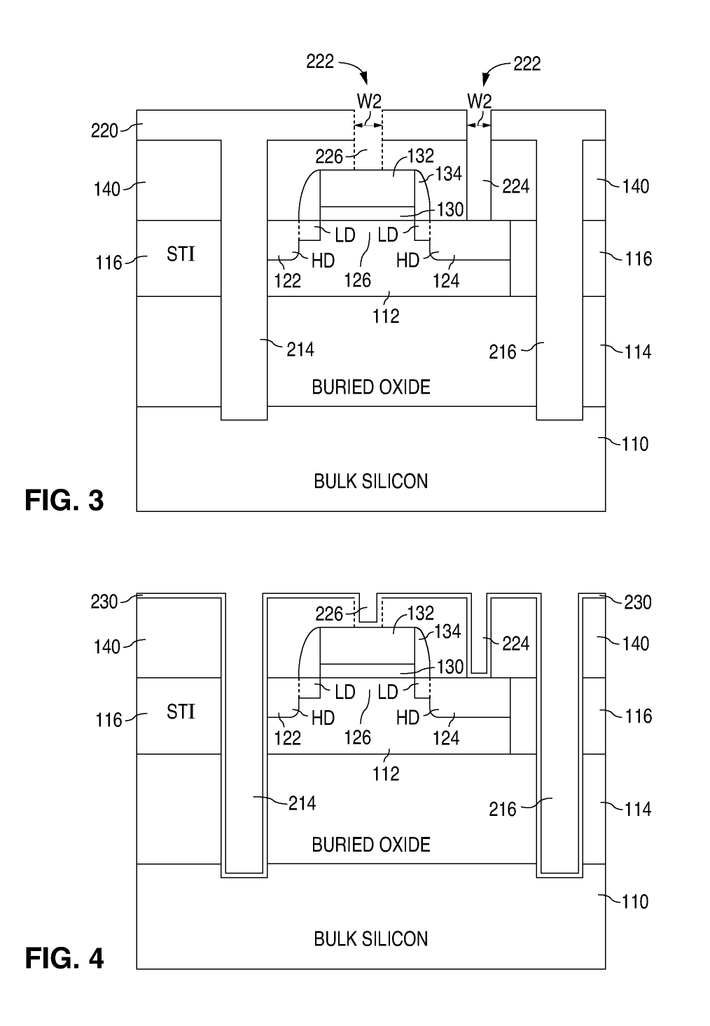

As shown in FIG. 3, after mask 210 has been removed, a masking material is formed on the top surface of dielectric layer 140, which also fills up the openings 214 and 216. The masking material is then patterned to form a mask 220 that has a number of openings 222 that expose the top surface of dielectric layer 140. Each of the openings 222, in turn, has a maximum cross-sectional width W2 that is less than the widths W1. For example, if the widths W1 of the openings 212 are 1 μm, then the widths W2 of the openings 222 can be approximately 0.22 μm to 0.5 μm.

After mask 220 has been formed, the regions exposed by the openings 222 in mask 220 are etched, such as with a plasma etch that is selective to silicon and polysilicon. The etch forms a first opening 224 that extends through a portion of dielectric layer 140 to expose the top surface of drain region 124, and a second opening 226 that extends through a portion of dielectric layer 140 to expose the top surface of gate 132. (Opening 226 is shown dashed because opening 226 exposes a portion of gate 132 that lies over STI region 116.)

Following this, mask 220 is removed. Mask 220 can be aggressively stripped with, for example, sulfuric-peroxide. Sulfuric-peroxide, in turn, is strong enough to ensure that all of the masking material formed in the openings 214 and 216 is effectively removed. (The order of the formation of masks 210 and 220 can alternately be reversed.)

As shown in FIG. 4, after mask 220 has been removed, a contact liner 230 is conformally deposited on dielectric layer 140 and in the openings 214, 216, 224, and 226 to line the openings 214, 216, 224, and 226. Contact liner 230, in turn, can be deposited as a layer of titanium and a layer of titanium nitride. Because the aspect ratio of openings 214 and 216 is approximately 4:1, contact liner 230 provides good step coverage. In the preferred embodiment, the titanium is deposited as a combination of both ion metal plasma (IMP) and plasma vapor deposition (PVD) to ensure good bottom and side wall coverage of the deposited titanium film.

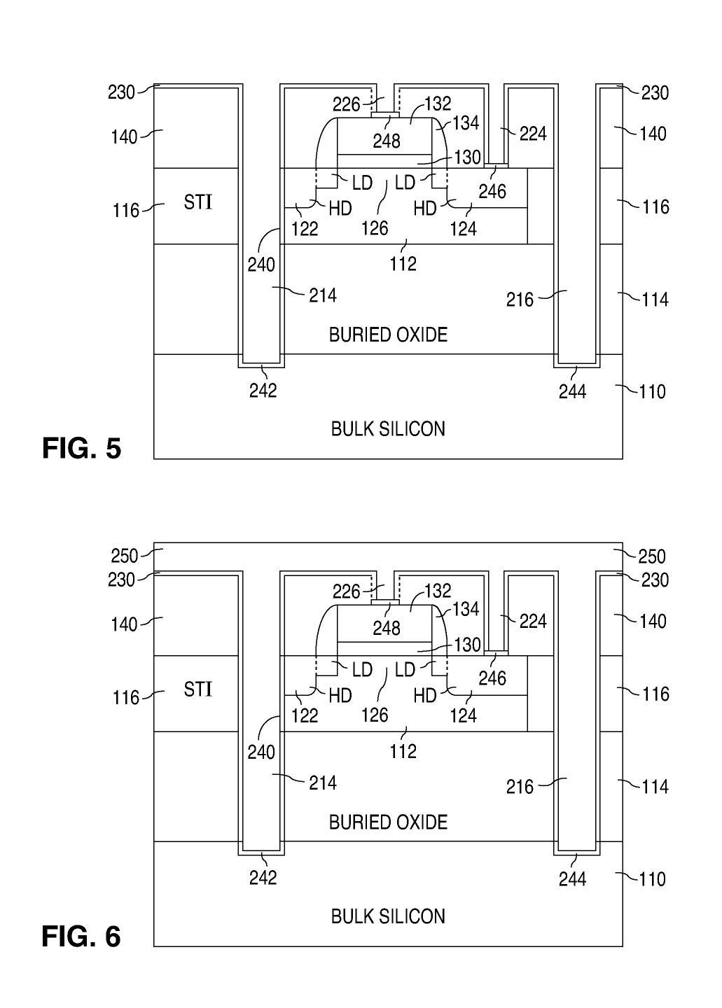

Following this, as shown in FIG. 5, contact liner 230 is subjected to a 650° C. rapid thermal process (RTP) in an N₂ ambient, which causes the titanium to react with the silicon and form a number of silicide regions. The number of silicide regions include a silicide region 240 that touches source region 122 and thin silicon region 112, a silicide region 242 that touches bulk silicon region 110 in opening 214, a silicide region 244 that touches bulk silicon region 110 in opening 216, a silicide region 246 that touches the top surface of drain region 124, and a silicide region 248 that touches the top surface of gate 132.

As shown in FIG. 6, after the silicide regions have been formed, a metal layer 250, such as tungsten, is deposited, such as by chemical vapor deposition (CVD), on the top surface of dielectric layer 140 to fill up the openings 214, 216, 224, and 226. The N₂ ambient of the RTP step fortifies the titanium nitride layer to ensure that no titanium is exposed during the metal layer (e.g., tungsten) deposition process. The metal layer can be deposited to have a thickness of, for example, approximately 0.6 μm to 1.0 μm over dielectric layer 140 to ensure that the openings 214, 216, 224, and 226 are completely filled.

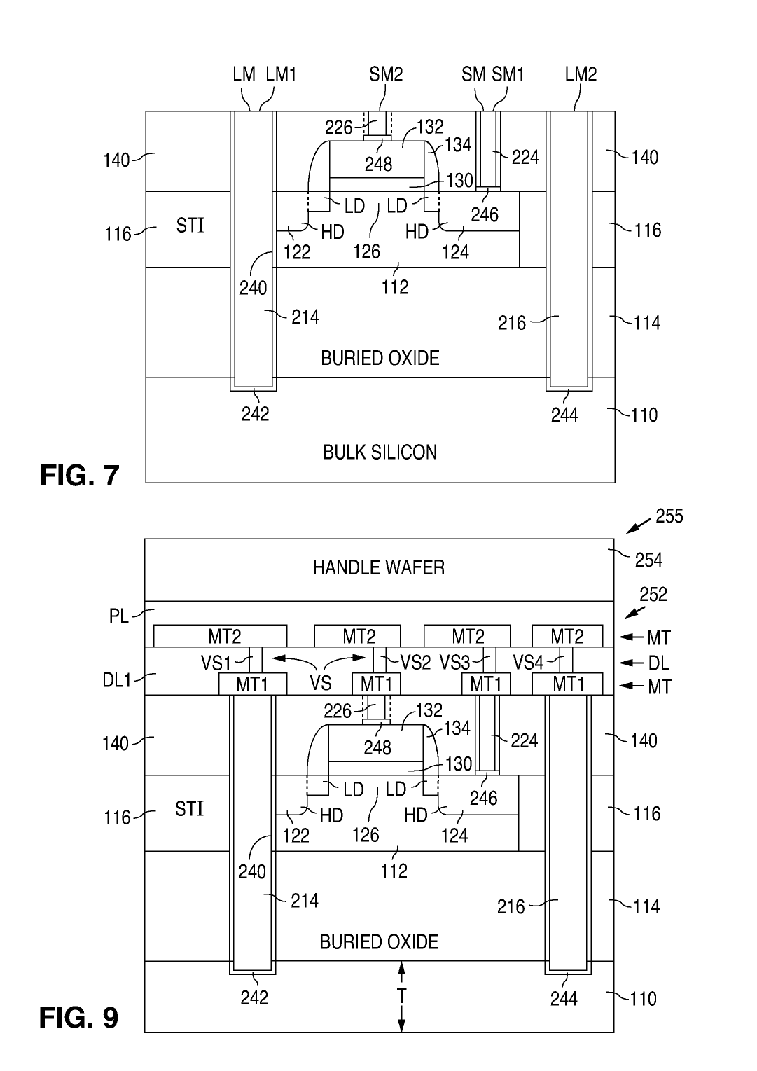

As shown in FIG. 7, after metal layer 250 has been deposited, metal layer 250 and contact liner 230 are planarized until metal layer 250 and contact liner 230 have been removed from the top surface of dielectric layer 140 to form a number of long metal contacts LM and a number of short metal contacts SM. The long metal contacts LM include a long metal contact LM1 in opening 214 that touches silicide region 240 and silicide region 242, and a long metal contact LM2 in opening 216 that touches silicide region 244.

The short metal contacts SM, in turn, include a short metal contact SM1 in opening 224 that touches silicide region 246, and a short metal contact SM2 in opening 226 that touches silicide region 248. Metal layer 250 and contact liner 230 can be planarized using, for example, chemical-mechanical polishing. (Current-generation chemical-mechanical polishers can polish up to 1.5 μm of tungsten off of dielectric layer 140.)

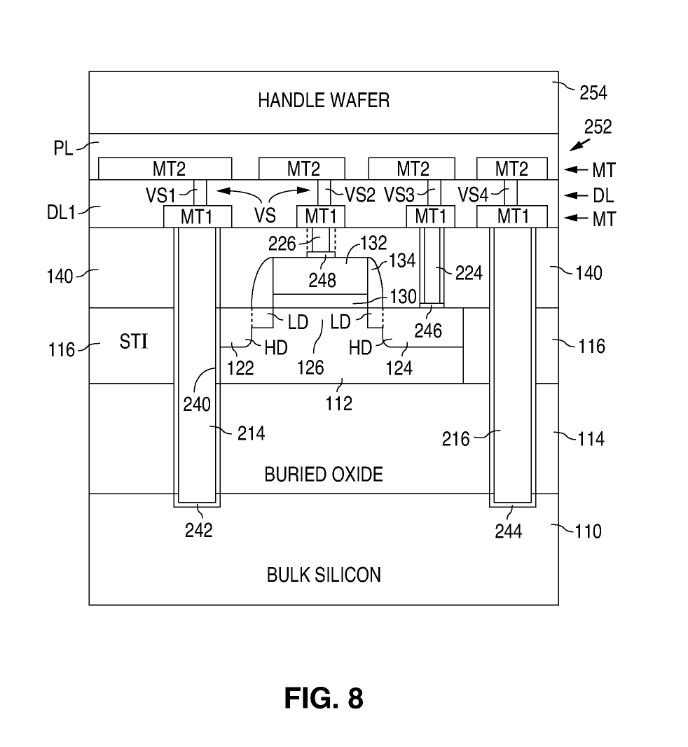

As shown in FIG. 8, after the long and short metal contacts LM and SM have been formed, a metal interconnect structure 252 is formed in a conventional manner to touch dielectric layer 140 and the metal contacts LM and SM. A metal interconnect structure is a structure that electrically interconnects the different devices together to form an electrical circuit.

Metal interconnect structure 252 includes a number of layers of metal traces MT. In the FIG. 8 example, a layer of metal-1 traces MT1 touch the metal contacts LM and SM, and a layer of metal-2 traces MT2 lie above the layer of metal-1 traces MT1. Metal interconnect structure 252 also includes a number of layers of inter-metal dielectric DL that lies between and touches adjacent layers of metal traces MT. In the FIG. 8 example, an inter-metal dielectric layer DL1 lies between and touches the layer of metal-1 traces MT1 and the layer of metal-2 traces MT2.

In addition, metal interconnect structure 252 also includes a number of vias VS that extend through the inter-metal dielectric layers DL to electrically connect together adjacent layers of metal traces TM, such as vias VS1, VS2, VS3, and VS4. Further, metal interconnect structure 252 includes a passivation layer PL that lies over and touches the top layer of metal traces MT.

Following the conventional formation of metal interconnect structure 252, a handle wafer 254 is temporarily attached to passivation layer PL using conventional MEMS processing techniques and materials so that the back side of SOI wafer 100 can be processed. Handle wafer 254 can be, for example, 750 μm thick.

As shown in FIG. 9, after handle wafer 254 has been attached to passivation layer PL, bulk silicon region 110 is thinned to a thickness T using conventional processes, such as a combination of back grinding and chemical-mechanical polishing, to form an SOI wafer 255. Bulk silicon region 110 can be originally formed to have a thickness of, for example, approximately 750 μm, and can be thinned to have a thickness T of, for example, approximately 200 μm. A final mirror like polish can be performed in order to reduce surface roughness of the back side of SOI wafer 255.

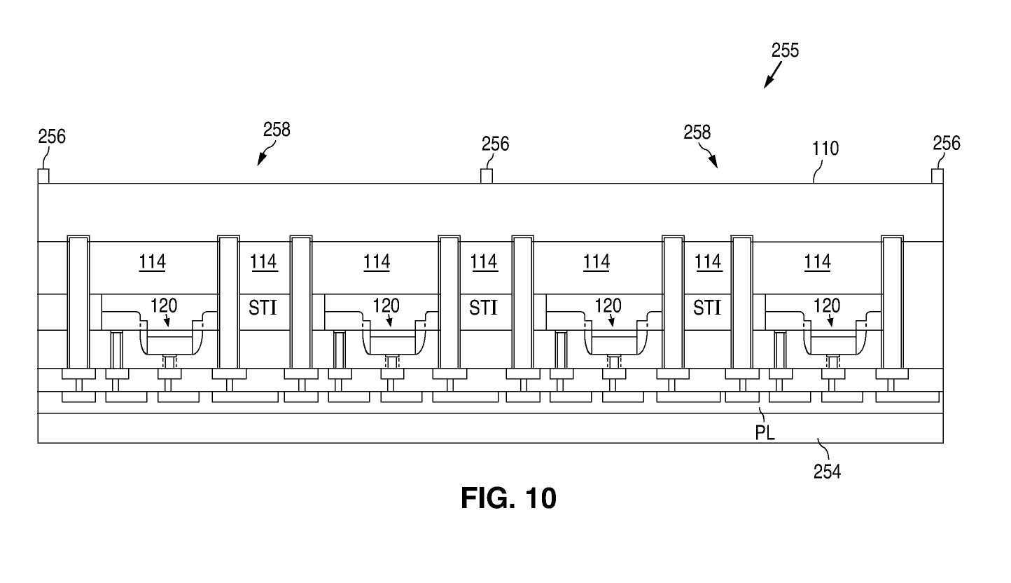

As shown in FIG. 10, once bulk silicon region 110 has been thinned, SOI wafer 255 is flipped over and a masking material is formed on the exposed surface of bulk silicon region 110. (FIG. 10 shows SOI wafer 255 with four adjacent MOS transistors 120.) The masking material is then patterned to form a mask 256 that has a number of openings 258 that expose bulk silicon region 110.

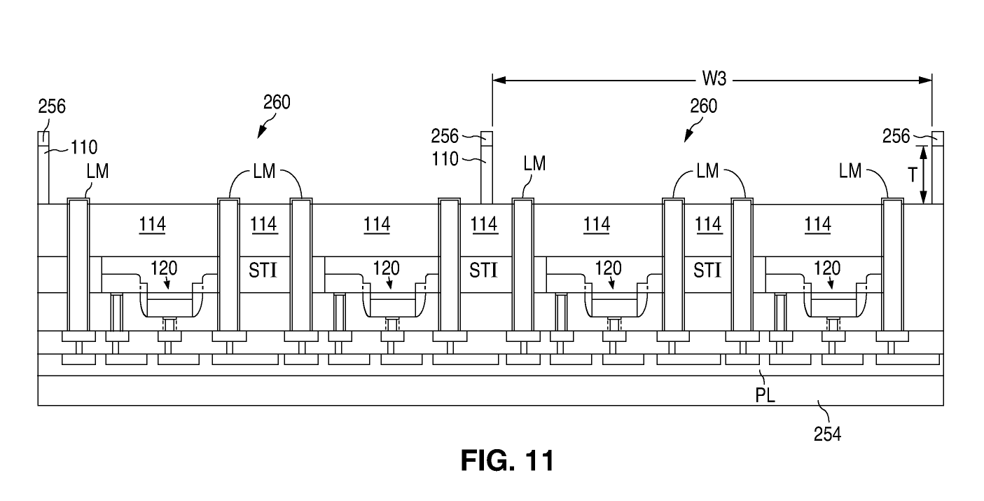

As shown in FIG. 11, after mask 256 has been formed, the regions exposed by the openings 258 in mask 256 are etched, such as with a Bosch process, to form a number of spaced-apart trenches 260 that each expose the buried insulation layer 114 and a number of long metal contacts LM. (Only two trenches 260 are shown for clarity.) The Bosch process, which is a well-known process that alternates between two different gas compositions in a reactor, is selective and stops effectively on buried insulation layer 114. In addition, the side walls of the trenches 260 can be slightly tapered with the Bosch etch by using an integrated isotropic etch step. Following this, mask 256 is removed.

Each trench 260, in turn, can have a maximum width W3 of, for example, 60 μm, a maximum length of, for example, 1000 μm, and a thickness T of, for example, 200 μm without effecting the structural stability of the overlying silicon and associated metal interconnect structure. It would be preferable, but not mandatory, for all of the trenches 260 to be of comparable size as the reactive ion etching (RIE) lag would result in the trenches 260 clearing to the buried insulation layer 114 at different times if the trenches 260 are of greatly different sizes.

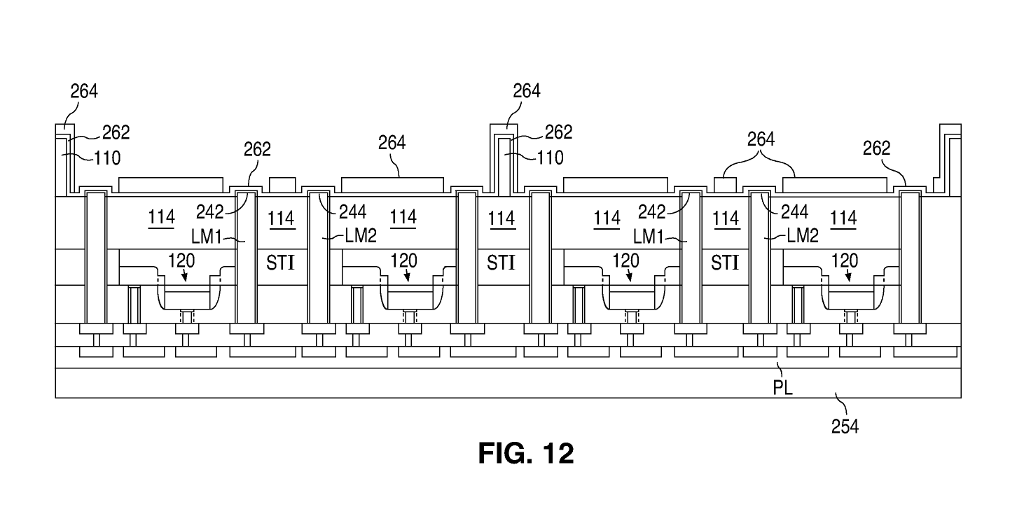

As shown in FIG. 12, following the removal of mask 256, a seed layer 262 is formed to touch bulk silicon region 110, buried insulation layer 114, and the silicide regions 242 and 244 of the long metal contacts LM1 and LM2. For example, seed layer 262 can be formed by depositing 300 Å of titanium, 3000 Å of copper, and 300 Å of titanium. (Seed layer 262 can also include a barrier layer to prevent copper electromigration if needed.) Once seed layer 262 has been formed, a plating mold 264 is formed on the top surface of seed layer 262. Plating mold 264 can be implemented with, for example, a spray of photoresist that is patterned to form the openings in plating mold 264.

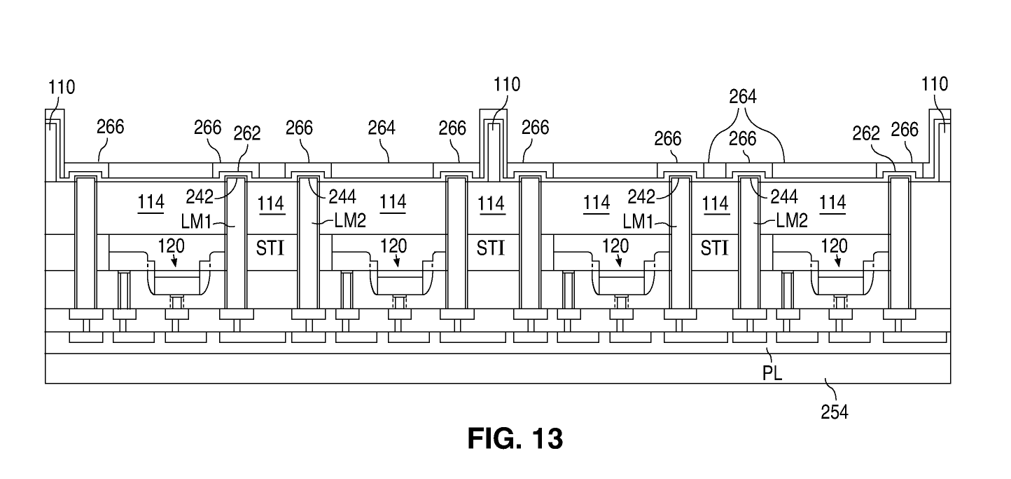

As shown in FIG. 13, following the formation of plating mold 264, the top titanium layer is stripped and copper is deposited by electroplating to form a number of copper traces 266 that are connected to the silicide regions 242 and 244 of the long metal contacts LM1 and LM2. The copper traces 266, in turn, are similar to a layer of copper traces formed in a conventional metal interconnect copper process, except that the copper traces 266 are formed in the trenches 260.

For example, one copper trace 266 can be connected to a number of long metal contacts LM1 by way of the silicide regions 242, while another copper trace 266 can be connected to a number of long metal contacts LM2 by way of the silicide regions 244. The copper traces 266 can be, for example, several microns thick. In addition, it is possible to support 5 μm design rules for the copper traces 266.

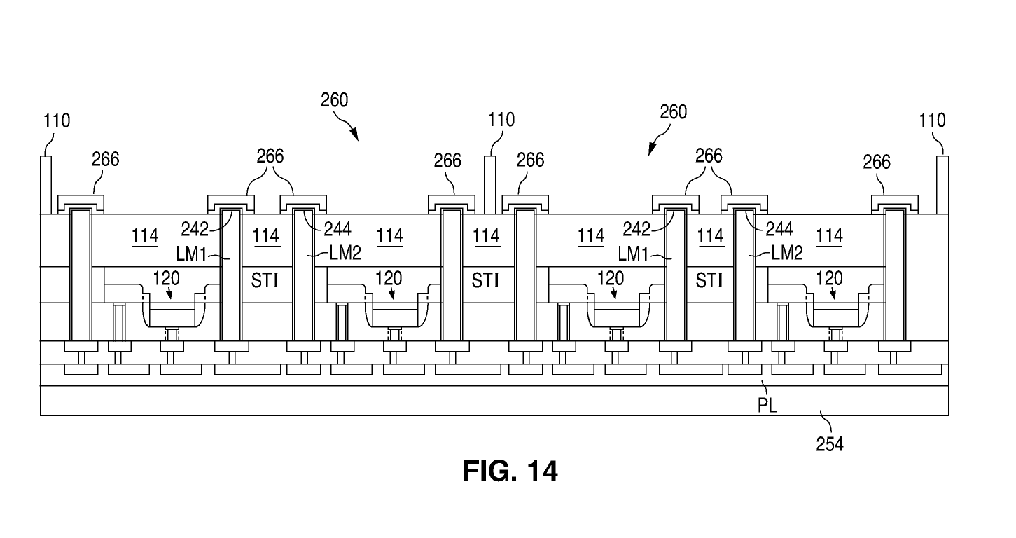

As shown in FIG. 14, after the electroplating, plating mold 264 and the underlying regions of the seed layer 262 are removed to expose bulk silicon region 110 and buried insulation layer 114. The method of the present invention can conclude at this point with the removal of handle wafer 254.

Alternately, however, since the bottom of buried insulation layer 114 is relatively flat, additional layers of copper traces can be formed on top of the copper traces 266. Further, copper traces can be formed to extend from trench 260 to trench 260 to make electrical connections with copper traces in an adjacent trench 260.

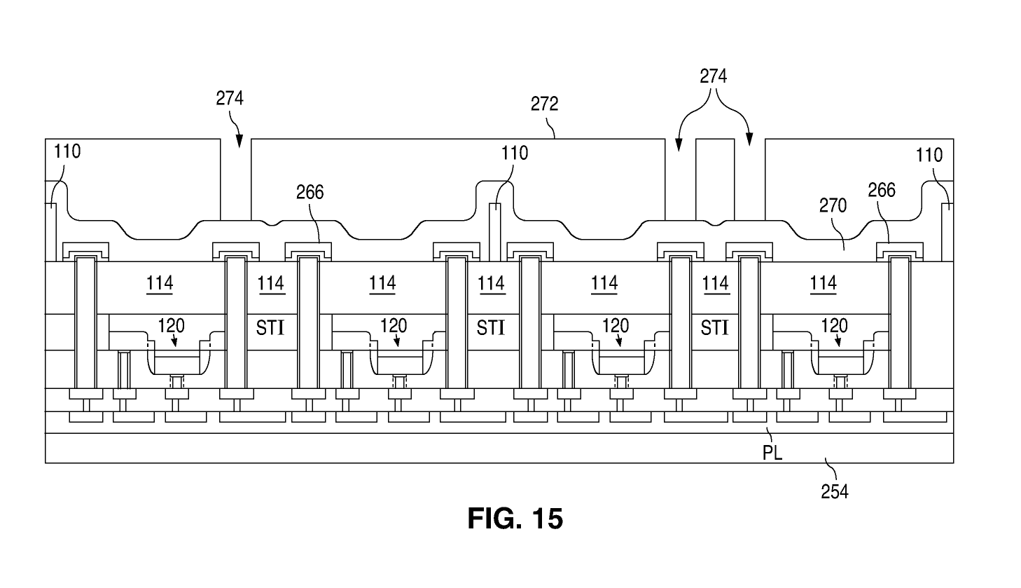

For example, as shown in FIG. 15, a second layer of copper traces can be formed by first forming a dielectric layer 270 on bulk silicon region 110, buried insulation layer 114, and the copper traces 266 following the removal of seed layer 262. Dielectric layer 270 can be implemented with, for example, SU-8 epoxy. Once dielectric layer 270 has been formed, a masking material is formed on dielectric layer 270. The masking material is then patterned to form a mask 272 that has a number of openings 274 that expose dielectric layer 270.

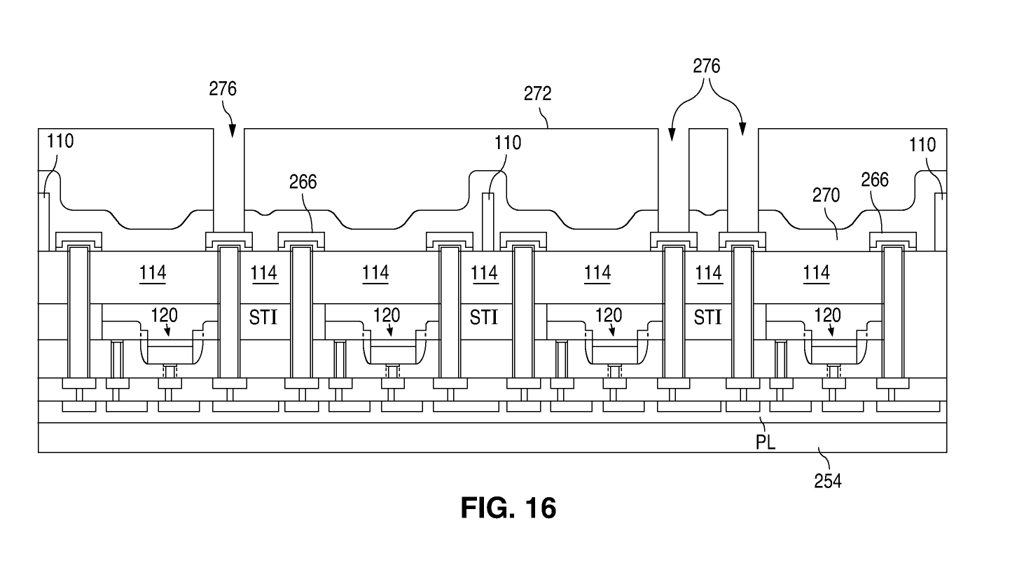

As shown in FIG. 16, after mask 272 has been formed, the regions of dielectric layer 270 exposed by the openings 274 in mask 272 are etched to form a number of openings 276. The openings 276, in turn, expose selected regions on the copper traces 266. Following this, mask 272 is removed.

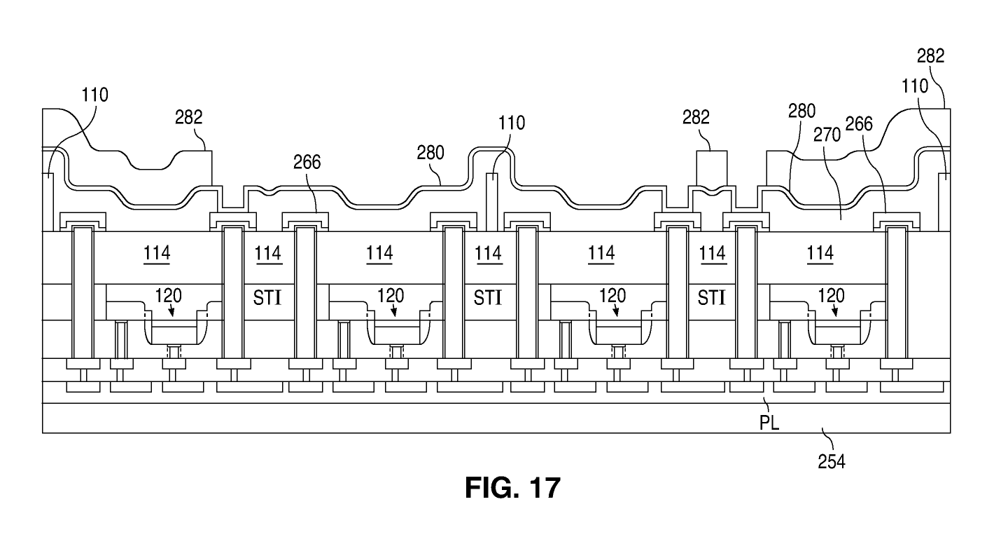

As shown in FIG. 17, after the removal of mask 272, a seed layer 280 is formed to touch dielectric layer 270 and the selected regions on the copper traces 266. For example, seed layer 280 can be formed by depositing 300 Å of titanium, 3000 Å of copper, and 300 Å of titanium. (Seed layer 280 can also include a barrier layer to prevent copper electromigration if needed.) Once seed layer 280 has been formed, a plating mold 282 is formed on the top surface of seed layer 280. Plating mold 282 can be implemented with, for example, a spray of photoresist that is patterned to form the openings in plating mold 282.

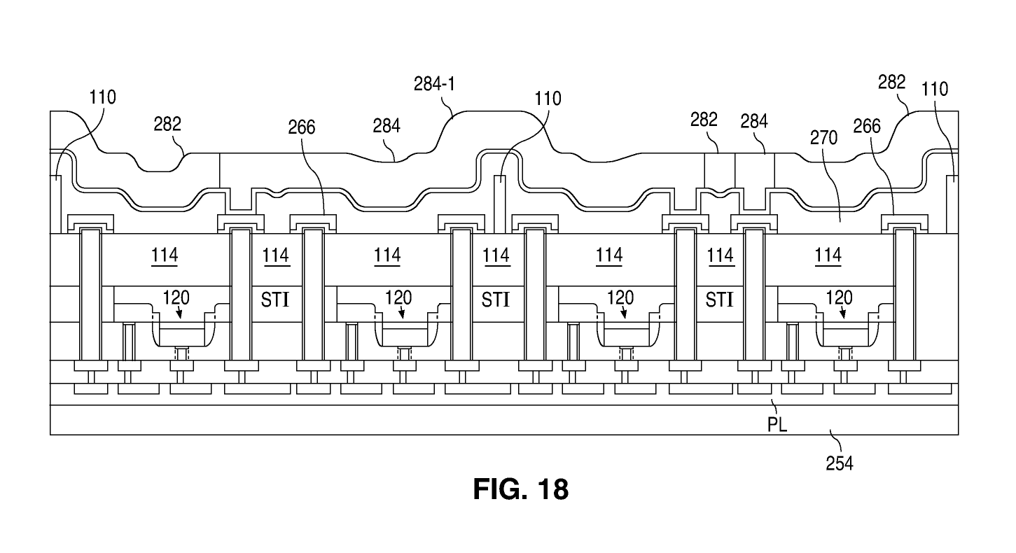

As shown in FIG. 18, following the formation of plating mold 282, the top titanium layer is stripped and copper is deposited by electroplating to form a number of copper traces 284 that are connected to the selected regions on the copper traces 266. The copper traces 284 can be thicker than the copper traces 266.

For example, one copper trace 284 can be connected to a number of copper traces 266 which, in turn, are each connected to a number of long metal contacts LM1 by way of the silicide regions 242, while another copper trace 284 can be connected to a number of copper traces 266 which, in turn, are each connected to a number of long metal contacts LM2 by way of the silicide regions 244.

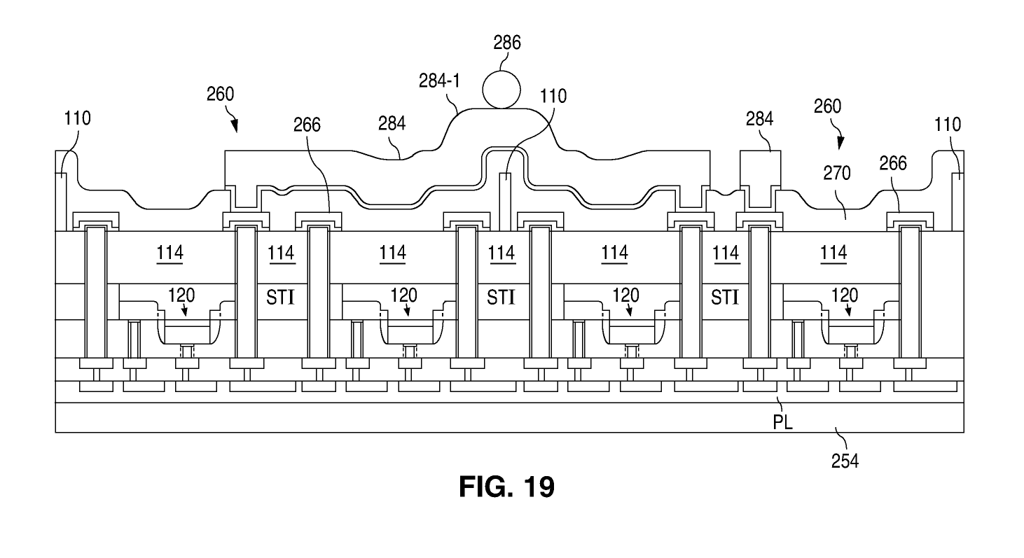

As shown in FIG. 19, after the electroplating, plating mold 282 and the underlying regions of the seed layer 280 are removed to expose dielectric layer 270. As further shown in FIG. 19, the copper traces 284 can include a copper trace 284-1 that extends from one trench 260 to an adjacent trench 260 to make electrical connections with copper traces 266 in an adjacent trench 260. In addition, solder balls, such as solder ball 286 can be attached to regions of the second copper traces 284, such as second copper trace 284-1, which step over the bottom surface of bulk silicon region 110. The solder balls can be formed in a conventional manner.

The method of the present invention can conclude at this point with the removal of handle wafer 254. Alternately, additional layers of copper interconnect can be formed.

Thus, an SOI wafer and a method of forming the SOI wafer with through-the-wafer long metal contacts LM, and trench based interconnect structures that electrically connect the through-the-wafer long metal contacts LM has been disclosed. The long metal contacts LM2 form through-the-wafer contacts that can be connected to the drains and gates of the transistors through the first layer of metal-1 traces MT1. In addition, the long metal contacts LM1 form through-the-wafer contacts that are connected to the sources and bodies of the transistors.

As a result, one of the advantages of the present invention is that the long metal contacts LM1 simultaneously bias the sources and bodies of the MOS transistors without increasing the size of the transistors. Many circuits utilize NMOS transistors where both the source and body are connected to the same bias voltage, such as ground, and PMOS transistors where the source and body are connected to the same bias voltage, such as VDD. Thus, the body of each of these transistors can be biased without increasing the size of the transistor.

Another advantage of the present invention is that the present invention provides multiple levels of copper interconnect in trenches on the bottom side of the SOI wafer, thereby increasing the flexibility of the metal interconnect structure as well as providing connection points for solder balls.

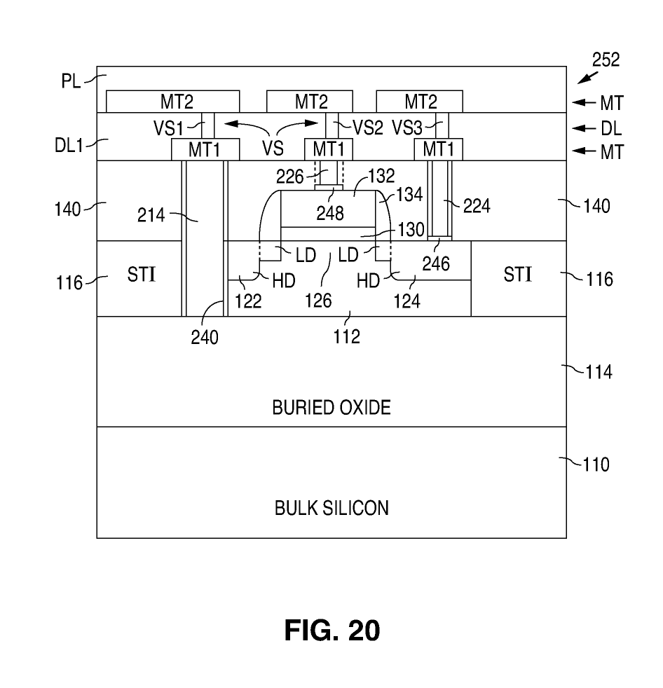

It should be understood that the above descriptions are examples of the present invention, and that various alternatives of the invention described herein may be employed in practicing the invention. For example, the sources and bodies of the MOS transistors can be simultaneously biased by forming only openings 214 through mask 210, and only to extend down to buried insulation layer 114 (or less) as shown in FIG. 20.

In this embodiment, the method concludes after the formation of metal interconnect structure 252. In the FIG. 20 embodiment, since opening 214 does not extend through buried insulation layer 114, the widths W1 can be smaller and still maintain an aspect ration of 4:1. Therefore, it is intended that the following claims define the scope of the invention and that structures and methods within the scope of these claims and their equivalents be covered thereby.

What is claimed is:

1. An electronic circuit comprising:
a bulk silicon region;
a buried insulation layer that touches the bulk silicon region;
a thin silicon region that touches the buried insulation layer, the buried insulation layer lying between and touching the bulk silicon region and the thin silicon region, the thin silicon region having a conductivity type;
a drain region of a transistor that touches the thin silicon region, the thin silicon region and the drain region having opposite conductivity types;
a dielectric layer that touches and lies over the drain region;
a long metal contact that touches the dielectric layer and the thin silicon region; and
a short metal contact that touches the dielectric layer and the drain region.

2. The electronic circuit of claim 1 and further comprising a source region of the transistor, the long metal contact touching the source region, the source region and the drain region having a same conductivity type.

3. The electronic circuit of claim 1 wherein the long metal contact includes a silicide region that touches the thin silicon region and the source region.

4. The electronic circuit of claim 1 wherein the long metal contact touches the buried insulation layer and the bulk silicon region.

5. The electronic circuit of claim 4 and further comprising a long metal contact that touches the dielectric layer, an isolation region, the buried insulation layer, and the bulk silicon region, the isolation region touching the buried insulation layer and the thin silicon region.

6. The electronic circuit of claim 5 wherein the long metal contact that touches the isolation region is spaced apart from the thin silicon region.

7. The electronic circuit of claim 6 and further comprising a plurality of spaced apart trenches in the bulk silicon region, a first trench of the plurality of spaced apart trenches exposing the long metal contact that touches the thin silicon region and the long metal contact that touches the isolation region.

8. The electronic circuit of claim 7 and further comprising a plurality of metal traces, a first metal trace of the plurality of metal traces in the first trench touching the long metal contact that touches the thin silicon region, a second metal trace of the plurality of metal traces in the first trench touching the long metal contact that touches the isolation region.

9. The electronic circuit of claim 8 and further comprising a plurality of metal lines, a metal line lying in the first trench to touch the first metal trace, and lying in a second trench of the plurality of trenches.

10. The electronic circuit of claim 9 and further comprising a solder ball that touches the metal line.

11. A method of forming an electronic circuit on a silicon-on-insulator (SOI) wafer comprising:
forming a first opening in the SOI wafer, the first opening exposing a dielectric layer and a thin silicon region of the SOI wafer, the thin silicon region having a conductivity type;
forming a second opening in the SOI wafer, the second opening exposing the dielectric layer of the SOI wafer and a drain region of a transistor, the dielectric layer touching and lying above the drain region, the drain region touching the thin silicon region, and having a conductivity type opposite to the conductivity type of the thin silicon region; and
simultaneously forming a long metal contact in the first opening, and a short metal contact in the second opening.

12. The method of claim 11 wherein the first opening exposes a source region of the transistor, the source region and the drain region having a same conductivity type.

13. The method of claim 11 wherein the long metal contact includes a silicide region that touches the thin silicon region and the source region.

14. The method of claim 11 wherein the first opening extends through a buried insulation layer of the SOI wafer and exposes a bulk silicon region of the SOI wafer, the buried insulation layer lying between and touching the thin silicon region and the bulk silicon region.

15. The method of claim 14 and further comprising:
forming a third opening in the SOI wafer simultaneously with forming the first opening, the third opening exposing the dielectric layer, an isolation region, the buried insulation layer, and the bulk silicon region of the SOI wafer, the isolation region touching the buried insulation layer and the thin silicon region; and
forming a long metal contact in the third opening simultaneously with forming the long metal contact in the first opening.

16. The method of claim 15 and further comprising thinning the bulk silicon region after the short metal contact has been formed.

17. The method of claim 16 and further comprising forming a plurality of spaced apart trenches in the bulk silicon region after the bulk silicon region has been thinned, a first trench of the plurality of trenches exposing the long metal contact in the first opening and the long metal contact in the third opening.

18. The method of claim 17 and further comprising forming a plurality of metal traces, a first metal trace of the plurality of metal traces in the first trench touching the long metal contact in the first opening, a second metal trace of the plurality of metal traces in the first trench touching the long metal contact in the third opening.

19. The method of claim 18 and further comprising forming a plurality of metal lines, a metal line of the plurality of metal lines lying in the first trench to touch the first metal trace, and lying in a second trench of the plurality of trenches.

20. The method of claim 19 and further comprising forming a solder ball to touch the metal line.
